(19) United States
(12) Patent Application Publication
(10) Pub. No.: US 2021/0005572 A1
(43) Pub. Date: Jan. 7, 2021

(54) CHIP FRONT SURFACE TOUCHLESS FLIP CHIP BONDERS

(71) Applicants: Dong Li, San Ramon, CA (US); Ying Ma, Pleasanton, CA (US); Ge Yi, San Ramon, CA (US); Zongrong Liu, Pleasanton, CA (US)

(72) Inventors: Dong Li, San Ramon, CA (US); Ying Ma, Pleasanton, CA (US); Ge Yi, San Ramon, CA (US); Zongrong Liu, Pleasanton, CA (US)

(21) Appl. No.: 16/504,271

(22) Filed: Jul. 7, 2019

(51) Int. Cl. H01L 23/00; H01L 21/56; H01L 21/683

(52) U.S. Cl. CPC H01L 24/83; H01L 21/563; H01L 21/6836; H01L 24/32; H01L 2224/32145; H01L 24/97; H01L 24/06; H01L 2224/04105; H01L 2224/95001; H01L 24/96

(57) ABSTRACT

A piece of chip-to-wafer and chip-to-chip bonding equipment, which has innovative designs enabling chip(s) from either a diamagnetic carrier or a diced wafer to expose the chip back side surface for pickup, is invented. The designs either use a levitation technology, or air dynamic, or a novel mechanical design to fulfill the chip front surfaces touchless requirement to avoid the chip surface contamination. The invented chip bonder is particularly useful for bonding applications which require using chips with zero tolerance of particle and/or contamination on the chip front surfaces or bonding surfaces.

### FIELD OF INVENTION

The invention is related to a chip bonder—an equipment to facilitate chip-to-chip and chip-to-wafer bonding. Particularly, the chip bonder is for applications such as direct bonding and hybrid bonding which request the front surfaces of the incoming chips or dies with zero chemical and/or particle contamination.

### BACKGROUND ART

Since the greatly slow down of the Moore's law in the last few years, the global semiconductor Industry has developed along two paths—very a few companies such as TSMC and Samsung still invest heavily along the more Moore's path, while more and more companies even including TSMC and Samsung chose to pursue so-called more than Moore's path.

In terms of technology approach, heterogeneous integration (HI) is the most relevant choice to represent the more than Moore's path.

From process side, there are three bonding approaches to facilitate heterogeneous integration, namely wafer-to-wafer, chip-to-wafer, and chip-to-chip. The first two approaches are much more cost-efficient. However, if the wafers providing chips have different chip sizes, or one kind of wafers with much lower chip yield, then the chip-to-wafer approach makes the only economic senses.

Unlike chip-to-wafer approach via eutectic bonding or adhesive bonding, some bonding technologies such as direct bonding and hybrid bonding using hard dielectric materials as the bonding interfaces require bonding surface roughness normally below one nanometer. In other words, there is zero tolerance to the bonding surface contamination caused by dicing, chip cleaning and handling, and bonding.

Currently there is no dedicated chip bonding equipment to resolve this chip surface contamination issue. Instead, some efforts such as collective chip-to-wafer bonding is used to resolve this issue by adding extra process steps. In collective bonding, a protection layer is used to cover the front side of the incoming wafer during wafer dicing. After wafer dicing, the chips are temporarily bonded on a handling wafer, then the protection layer is removed before wafer-to-wafer bonding. However, this causes issues such as bonder head contamination, low bonding accuracy and increased production cost.

### SUMMARY OF THE INVENTION

In this invention, a dedicated chip bonding tool is proposed with some novel approaches to avoid chip front surface contamination after wafer dicing and chip cleaning to enable direct chip-to-wafer bonding. The key idea is to avoid any physical contact to the chip front side through novel designs of chip picking and handling solutions using various invented technologies based on various physics principles.

In our invented new equipment, the hardware is separated into three portions: the 1^{st} part is a chip pickup station; the 2^{nd} part is the chip flip and levitation station; the 3^{rd} part is the alignment and bonding station. Of course, for cost saving purpose, the 2^{nd} and 3^{rd} part can be combined into one station. In other words, the chip flipping and bonding heads are combined into one. Despite the cost saving, the downside of such a design is more risky in terms of dust generation as the combined flipping and bonding component has more moving parts.

As to the 1^{st} part of chip supply/pickup station, we have proposed two main approaches: one is using novel diamagnetic chip holders with dedicated designs for our proposed pickup station to enable chip pickup from the chip bottom surface for chip flipping; the other is for handling diced wafers with combination of chip detachment from the dicing tape and pickup with a specially designed pickup tool approaching from the chip backside surface.

For the 2^{nd} chip flip and levitation station, the flipping tool picks up the chip from the 1^{st} station then puts on an acoustic wave levitation station so that the chip front surface (or the chip bonding surface) will never get touched.

The 3^{rd} station is the bonding station with a bonding head, which picks the chip from the 2^{nd} station at the chip bottom surface then moves into the 3^{rd} station for optical alignment followed by bonding. The bonding can be done at room temperature and even zero add-on force. The bonding is done between two very surfaces due to the van der Waals force between the bonding surfaces.

In one of the design, before the chip flipping or before bonding, a chip surface activation treatment can be done in the same station (either in the 2^{nd} or 3^{rd} station) or in another dedicated station as an option.

In this invention, various novel technical solutions particularly the 1^{st} station and the 2^{nd} station, only allow the chip handling tools and mechanism touch the bottom surfaces of the chips, therefore cause minimal chip front surface contamination. Our proposed chip bonders provide a great equipment solution for both direct bonding and hybrid bonding.

### BRIEF DESCRIPTION OF THE DRAWINGS

FIG. 1 an embodiment of hybrid bonding with oxide and Cu at the bonding interfaces.

FIG. 2 one of the embodiments of proposed chip bonders for chip-to-wafer or chip-to-chip bonding.

FIG. 3 embodiments of chip carriers for single chip or muliple chips made by diamagnetic material eg. pyrolytic carbon (PyC) for magnetic chip levitation for chip pickup from the chip bottom surface to avoid any front surface contact.

FIG. 4 one of the embodiments of chip detachment and floating mechanism from diced wafers with electrostatic levitation mechanism.

FIG. 5 one embodiment of chip detachment and floating mechanism from diced wafers using air dynamic non contact pickup heads.

FIG. 6 an embodiment of chip detachment by mechanical method from a diced wafer using a pickup method which only touches the chip bottom surface.

FIG. 7 an embodiment of chip detachment and floating mechanism using acoustic wave levitation.

FIG. 8 an embodiment of chip detachment and pickup using pin-pushing and chip fishing from side with only chip bottom surface touched.

FIG. 9 one of the embodiments of flipped chip sitting stand by acoustic levitation.

FIG. 10 one of embodiments of flipped chip sitting stand using pure water surface tension.

### DETAILED DESCRIPTION

The following numerous specific detail descriptions are set forth to provide a thorough understanding of various embodiments of the present disclosure. It will be apparent to one skilled in the art, however, these specific details need not be employed to practice various embodiments of the present disclosure. In other instances, well known components or methods have not been described.

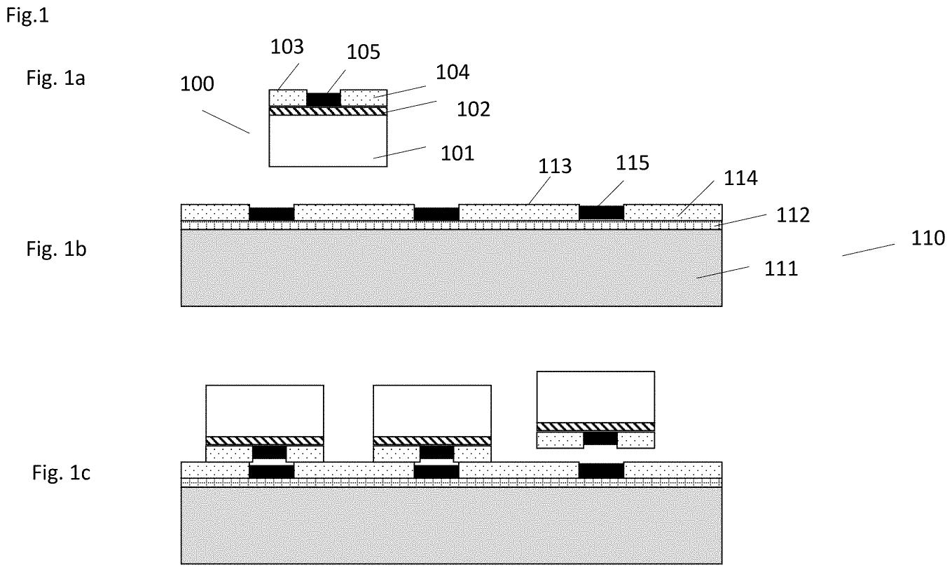

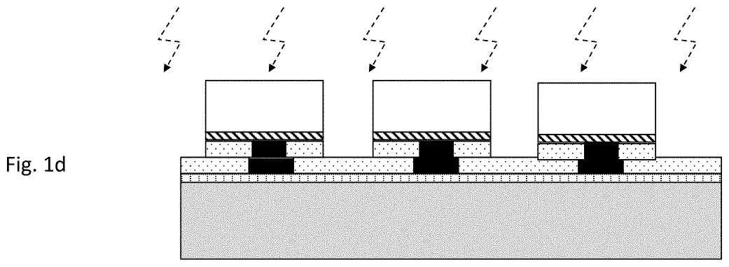

FIG. 1a-e describe an embodiment of a process flow for chip-to-wafer hybrid bonding, one of the bonding applications which require bonding surfaces with zero tolerance of particle and/or chemical contamination. The invented method is also very important for other bonding applications such as direct bonding between dielectric and dielectric material or metal and metal.

FIG. 1a shows a component chip 100 for the chip-to-wafer (also can be used for chip-to-chip) bonding. It has substrate 101, on which functional device layer 102 is formed. At the bonding interface 103, there is non-polymer dielectric bonding layer 104, in which the metallic connect 105 is buried with a few nanometers recess from the exact dielectric bonding surface 103. The non-polymer bonding layer 104 is normally SiO₂ but other dielectric materials such as SiN, SiCN, SiC and AlOx can be used as well.

FIG. 1b is an embodiment of wafer 110, which includes wafer substrate 111, above which are the function device layer 112; bonding interface 113, non-polymer dielectric bonding layer 114 and the metallic connect 115, which is recessed a few nanometers from the bonding surface 113. Again the non-polymer bonding layer 114 is normally SiO₂ but other dielectric materials such as SiN, SiCN, SiC and AlOx can be used as well.

FIG. 1c is an embodiment of chip-to-wafer bonding process. After some alignment procedure is done, chip 100 on the bonding head (not shown here in the Figure) approaches to the wafer 110, while the distance between the two bonding interfaces 103 and 113 is close enough (below 1 nm), the van der Waals force is kicked in and lock/hold chip 100 in the place on top of the wafer 110. The van der Waals force is the highly distance-dependent interaction between atoms or molecules. To ensure the bonding success without defects, there are two requirements: one is the surface roughness of incoming surface 103 and 113 should be all below 1 nm (normally <0.5 nm), the other is there should be no particle contamination larger than 1 nm, literally no contamination is allowed on the interfaces of 103 and 113. Normally, it is relatively much easier to achieve zero contamination for wafer 110, which people have yearly accumulated experience to mitigate the particle contamination. However, on the other hand, it is much difficult to maintain the incoming chips 100 surface contamination. As such, an ideal bond or designed for chip-to-wafer or chip-to-chip hybrid/direct bonding should not allow any contact of the incoming chip bonding surface 103 during the bonding process as described in FIG. 1c. Also it is notable that the metallic contacts of 105 and 115 are not in contact as they are both recessed deliberately from the bonding surfaces 103 and 113.

FIG. 1d is an embodiment of the heating process after chip-to-wafer bonding for closing up the dish gap between metal contacts of 105 and 115. 104 and 114 in FIGS. 1a and 1b are dielectric bonding materials.

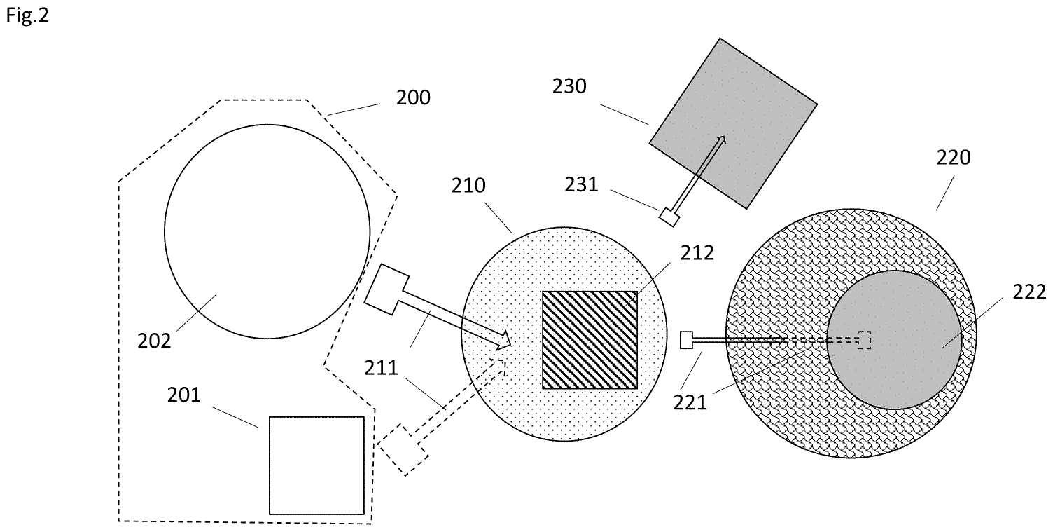

FIG. 2a is an embodiment of proposed chip bonder station configuration. It includes chip supply/pickup station 200, flipped chip sitting station 210, chip bonding station 220 and optional surface activation station 230. One common design feature for our proposed chip bonder is that the chip front surface, which is the bonding interface, will not be touched at all through every process and handling steps in the bonder to minimize the surface contamination. The chip supplier/pickup station 200 supplies chips for the whole chip bonder and it has two source stations: one is for individual chip pickup station 201 and the other—diced wafer station 202. The flipped chip sitting station 210 has a chip pickup-flip arm/tool 211, which pickup the chips from chip pickup station 200, then flip the chip, then put on the chip levitation stand 212. We proposed a dedicated flipped chip station so that we can separate the pickup-flip mechanics from the bonding head to simplify the mechanical designs and reduce the complications of the bonding head, which needs much better mechanical accuracy once chip-to-wafer or chip-to-chip alignment is done. The bonding station 220 has a bonding head 221, which pickups chips from the flipped chip sitting stand 212 then bonds on the wafer on the bonding substrate stand 222. In the proposed chip bonder, there is also an optional station 230 for bonding surface activation, which can pick either chip from flipped chip sitting stand 212 or wafer/chip from bonding substrate stand 222 for surface activation treatment using the pickup tool 231, then return to their dedicated stands before bonding process. As stated previously, when the bonding accuracy is not an issue, there is no need to separate the chip flip from chip bonding head. Under this circumstance, the system can be simplified by removing the station 210 with a modified bonding station with a bonding head capable of doing chip flipping movement then chip bonding movement. If so, then the system could only have station 200 and station 220 with the optional station 230 depending on the details of the bonding process steps.

For a 4-station chip bonder system proposed here, the process flow between the stations is as follows: a chip starts from chip supply/pickup station 200, which has a mechanism to enable either chip on the chip carrier or chip on diced wafer to expose the bottom surface of the die, then the pickup tool 221 picks up the chip from its bottom side then flip it over with its front surface down on the flipped chip sitting stand 212; after that, the pickup tool 231 then picks up the chip from its bottom side and hold it from bottom side during surface activation in the station 230; After surface activation, the pickup tool 231 puts the chip back to the station 210 on the flipped chip sitting stand to allow bonding heads 221 to pick up the chip from its bottom side to do alignment followed by chip bonding on the wafer/chip existing on the bonding substrate stand 222 in the bonding station 220.

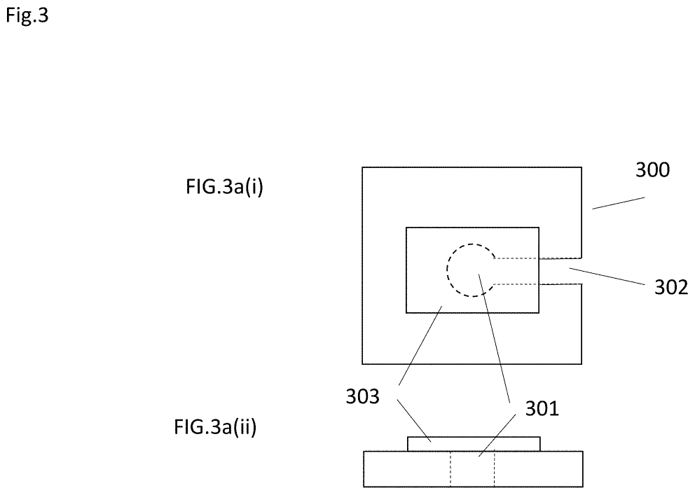

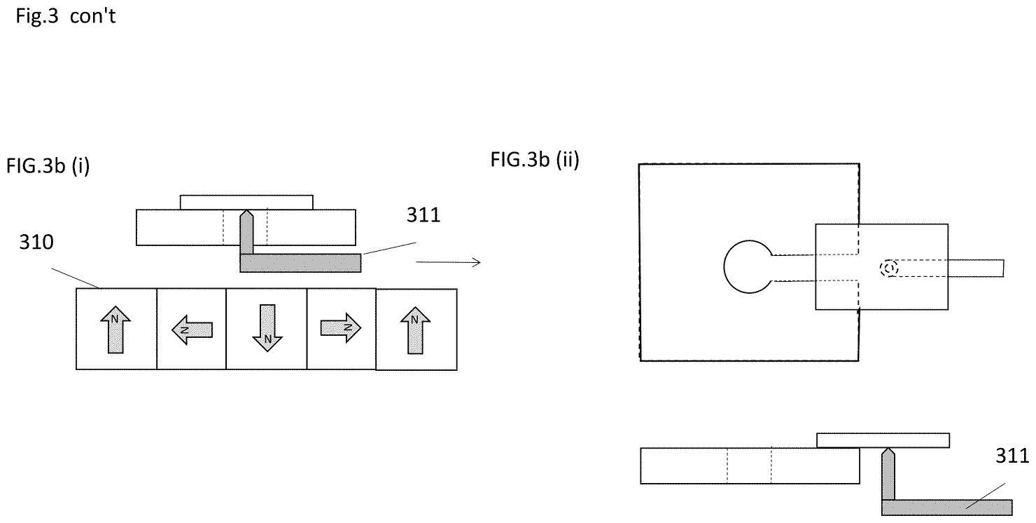

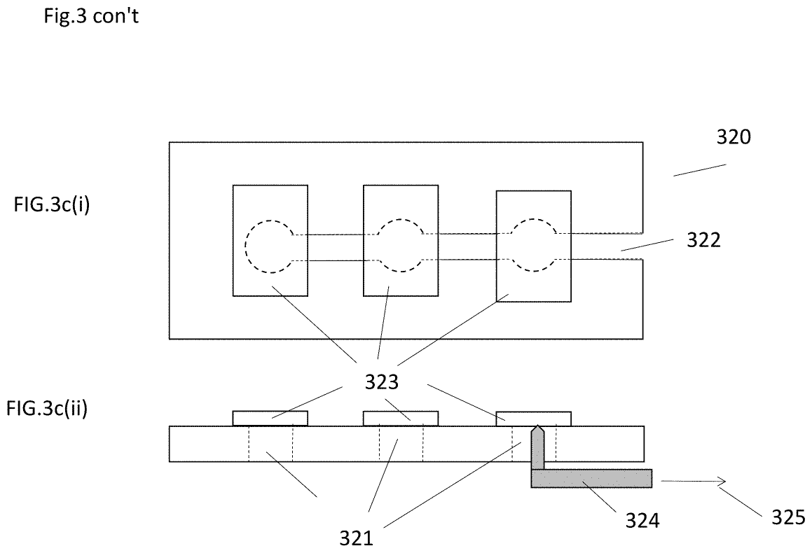

FIG. 3 shows an embodiment of a chip carrier for single chip and muliple dies made by diamagnetic materials such as pyrolytic carbon (PyC) for diamagnetic levitation for chip pickup from the bottom side of the chip to avoid any front side contact for individual chip pickup station 201, as shown in FIG. 2. The carrier 300 is one of the accessories, coming with the proposed chip bonder, provided to chip suppliers/manufacturers to secure and hold the dust-free chips for chip holding and transporting. Considering the PyC could also generate particles, a special treatment such as polymer coating is implemented for particle control purpose. The carrier 300 can be reused.

FIG. 3a(i) is a top down side view of a single chip carrier and its front side view is down in FIG. 3a(ii). The chip carrier 300 is made of diamagnetic materials such as PyC with cut-out hole 301 and a chip retreat path 302, which allow the chip 303 can be accessed from the bottom side at 301 and retreated out along the path 302. FIG. 3b shows how the carrier 300 with chip is levitated over a hard magnet system and how to pull the chip out. FIG. 3b(i) is from side schematic view with carrier made of diamagnetic material such as PyC floating on top of a magnets combination 310 in Halbach arrays configuration, which doubles the strength of the magnetic field to push the carrier with chip floating further away from the surface of the magnet combination 310 to provide enough space for the chip pickup tool 311 to access the bottom surface of the chip from below. Although the hard magnet is used here to provide levitation, it can be replaced by an electromagnet, preferably with soft magnetic core to further boost the magnetic field strength. In fact, using electromagnetic has better control on the field strength therefore the levitation, particularly the floating distance between the chip front surface and the top surface of the electromagnet. FIG. 3b(ii) shows the chip is retreated from the retreat path 302 by the pickup tool 311. As it is shown here, during all these steps, only the bottom side of the chip is touched.

FIG. 3c is similar to what have been shown in FIG. 3a but a carrier for multiple chips 320 with access holes 321 and retreat path 322 linked to access holes 321, which allow the chips 323 can be accessed and retreated by chip pickup tool 324 from the bottom sides of the chips along the direction indicated by the arrow 325.

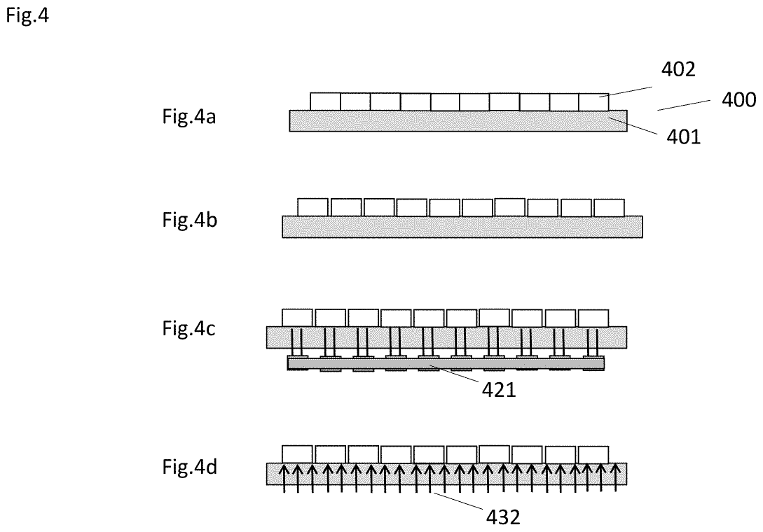

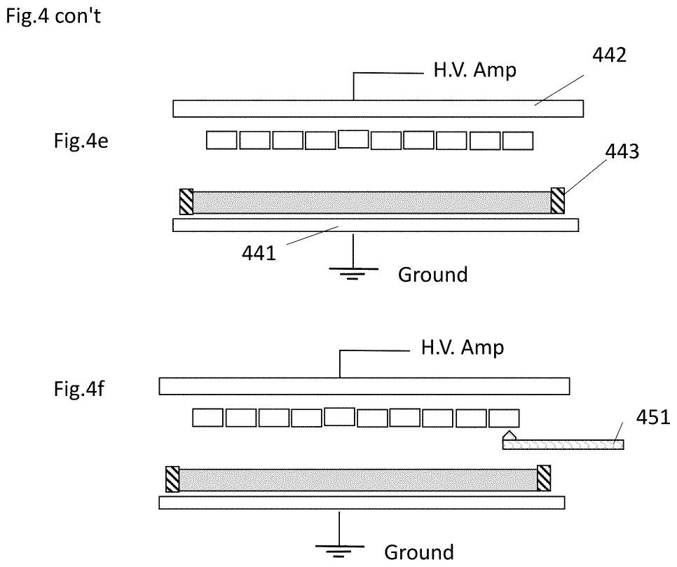

FIG. 4 shows an embodiment of the chip detaching and floating from a diced wafer on the diced wafer station 202 (shown in FIG. 2) via the electrostatic levitation so that the pickup tool is capable of accessing the chip from its bottom side. As shown in FIG. 4a, the incoming wafer system 400 has a diced wafer 402 sitting on a piece of UV sensitive dicing tape 401 with all the necessary post dicing front surface treatment to ensure there is no front surface particles and contamination for chip-to-wafer or chip-to-chip. Then the dicing tape is stretched to establish some gaps between the diced chips as shown in FIG. 4b. In fact the process described in FIG. 4b is not necessary to get done on the proposed system on its diced wafer station. After the dicing tape stretching, the chips are electrically charged from the bottom side by charging device with metallic pins 421 as shown in FIG. 4c. Then in order to pickup chip 431, a UV light radiation 432 is used from the back of dicing tape to reduce the stickiness (or adhesive force strength) locally as shown in FIG. 4d. To enable the chips to float via electrostatic levitating, a high voltage is applied between the ground electrode 441 and top electrode 442 while dicing tape is hold firmly by a mechanical clamp device 443. As shown in FIG. 4e, the chip under the electrostatic force is now floating within the gap between the pair of electrodes, which enables the chip pickup tool 451 to pick up the chip from edge to center one-by-one or in parallel fashion from the bottom surfaces of the chips as shown in FIG. 4f.

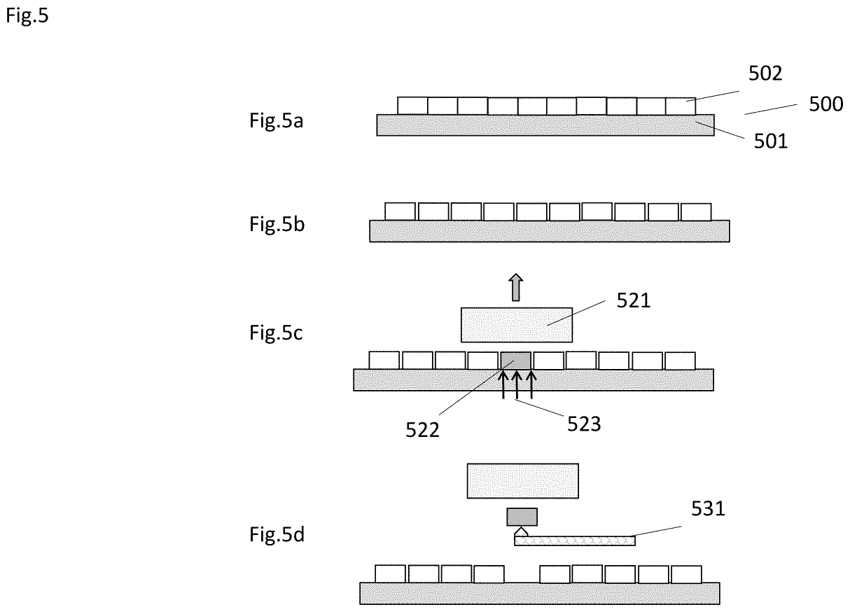

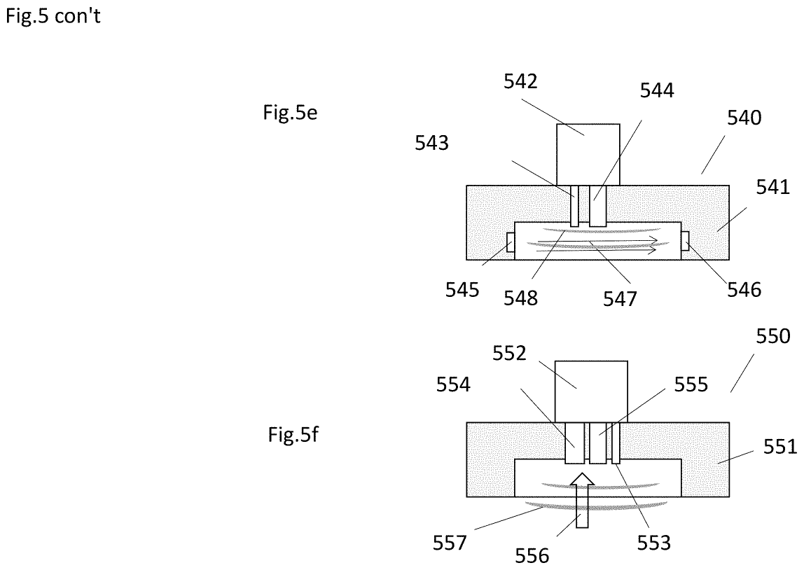

FIG. 5 shows an embodiment of the chip detaching and floating from a diced wafer on the diced wafer station 202 (shown in FIG. 2) via a specially design non-contact pickup tool based on air dynamic design. As shown in FIG. 5a, the incoming wafer system 500 has a diced wafer 502 sitting on a piece of UV sensitive dicing tape 501 with all the necessary post dicing front surface treatment to ensure there is no front surface particles and contamination for chip-to-wafer or chip-to-chip bonding. Then the dicing tape 501 is stretched to establish some gaps between the diced chips as shown in FIG. 5b. In fact the process described in FIG. 5b is not necessary to get done on the proposed system on its diced wafer station. As shown in FIG. 5c, before the specially designed and engineered air dynamic based pickup head 521 to approach the designated chip 522, the UV radiation 523 is shined from the backside of the chip 522 to weaken the adhesive force strength between the chip and the dicing tape. The pickup head 521 lifts the chip 522 so that the pickup and chip flipping tool 531 can access the chip bottom surface. FIG. 5e and FIG. 5f provide two kinds of design schematic drawings showing the air dynamic based on Bernoulli's Principle.

In details, FIG. 5e shows an embodiment of an air dynamic pickup head design. The pickup head 540 comprises pickup head body 541, which has a holder 542 to mechanically link to external mechanism to enable the heads movement; a distance sensor 543 either a laser distance sensor or more likely a capacitance based approximate sensor, an optional acoustic wave generator 544, and a pair of gas flow inlet 545 and outlet 546. The working principle is as follows: the gas flow between the gas outlet 545 and outlet 546 laterally indicated by the arrows 547, generates a pickup force on the designated chip based on Bernouli's principle. The sensor 543 detects the location of the chip in respect to the pickup head 540. The pickup force is based on reading from the sensor 543, with the force balance between the pickup force and the gravity of the chip with extra assistance from the optional acoustic generator 544 to avoid the chip's front surface touching the pickup head by generated acoustic wave 548 to push the chip move away from the pickup head.

FIG. 5f provides an alternation embodiment of the pickup heads design based on air dynamic. The proposed pickup head 550 comprises pickup head body 551, which has a holder 552 to mechanically link to external mechanism to enable the heads movement; a distance sensor 553 either a laser distance sensor or more likely a capacitance based approximate sensor, a vacuum sucking inlet 554, and an optional acoustic wave generator 555. The working principle is as follows: the vacuum sucking inlet will generate a pickup force with flow control indicated by the arrow 556 and inlet special air dynamic design to generate a uniform pickup force for the designated chip; a feedback control mechanism is established based on the distance sensing signal from the sensor 553 with balance between lifting force from inlet 554 and the gravity of the chip. The optional acoustic wave generator provides an acoustic wave 557, which can push the chip away from the pickup head and avoid any contact of the front surface of the designated chip.

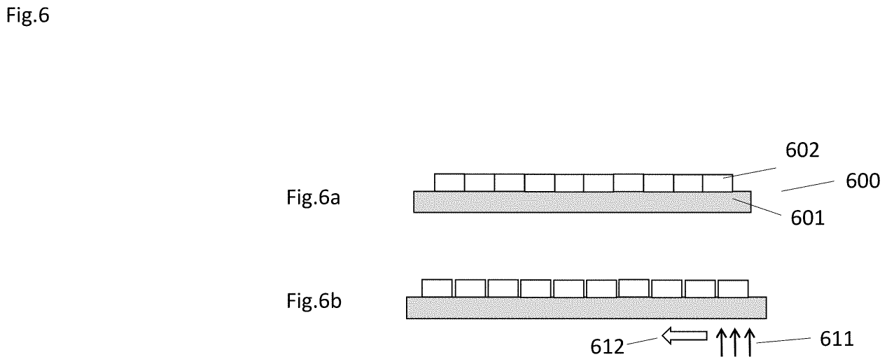

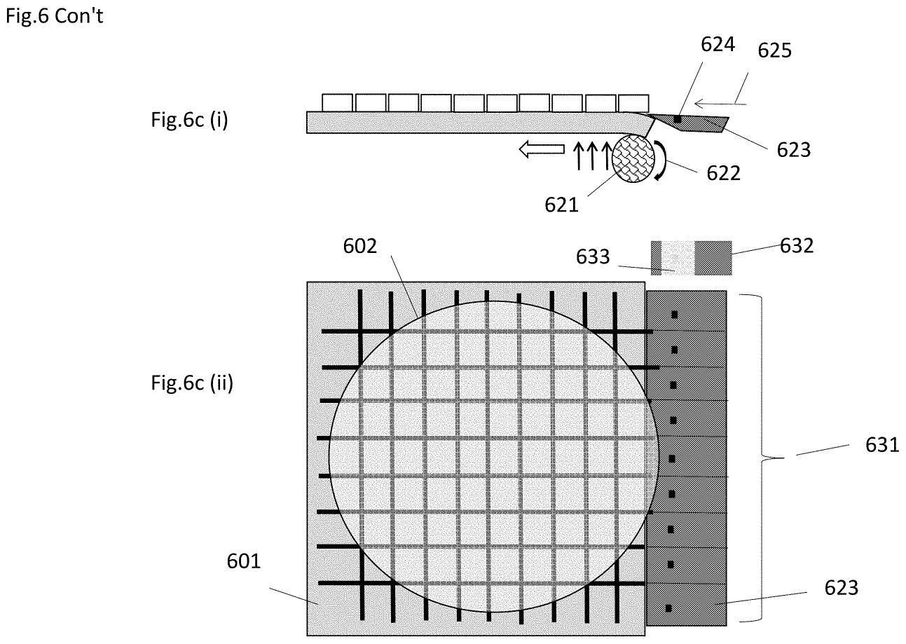

FIG. 6 is an embodiment of chip detachment by a mechanical method from diced wafer using a pickup method which only touches the chip bottom side. As shown in FIG. 6a, the incoming wafer system 600 from wafer suppliers has a diced wafer 602 sitting on a piece of UV sensitive dicing tape 601 with all the necessary post dicing front surface treatment to ensure there is no front surface particles and contamination for chip-to-wafer or chip-to-chip bonding. Then the dicing tape is stretched to establish some gaps between the diced chips as shown in FIG. 6b. In fact the process described in FIG. 6b is not necessary to get done on the proposed system on its diced wafer station. After dicing tape stretching, a line-shape localized UV radiation 611 with the width of the wafer diameter is implemented starting from the wafer edge and gradually move along the direction indicated by the arrow 612 cross the wafer to weaken the adhesive strength of the UV dicing tape. A dicing tape peel off cylinder wheel 621 is then attached the bottom side of the dicing tape and rotated with a direction indicated by arrow 622. As show in FIG. 6c(i), following the peel off cylinder wheel 621, there is a front wedge-shape chip pickup tool 623 with a vacuum sucking open 624 moving in along the direction indicated by arrow 625 for picking up the chips. The top-down view of FIG. 6c(i) is shown in FIG. 6c (ii). In fact, the single chip pickup tool 623 at the end is just one of similar tools, which make the array 631 with total width at least equal to the diameter of the wafer. The total number of chip pickup tools within 631 matches the total number of full chips and partial chips along the diameter of the diced wafer 602 on dicing tape 601. At the end of 631, a single pickup tool 632 with chip 633 is shown here to illustrate the single pickup tool 632 with chip 633 can be separated from the array 631 and moved away from the array to do the subsequent chip flipping step.

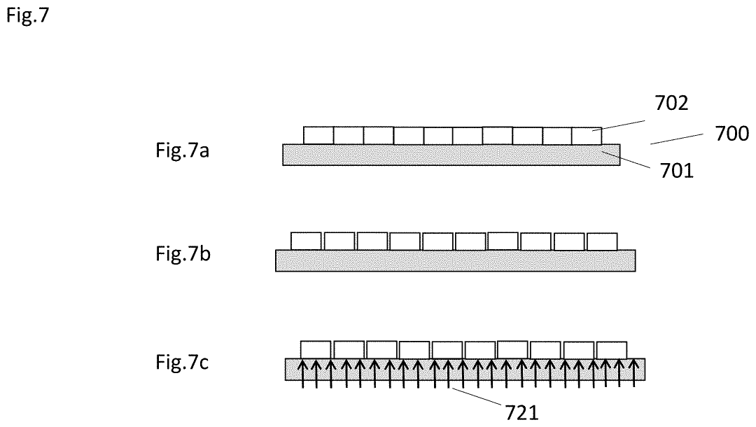

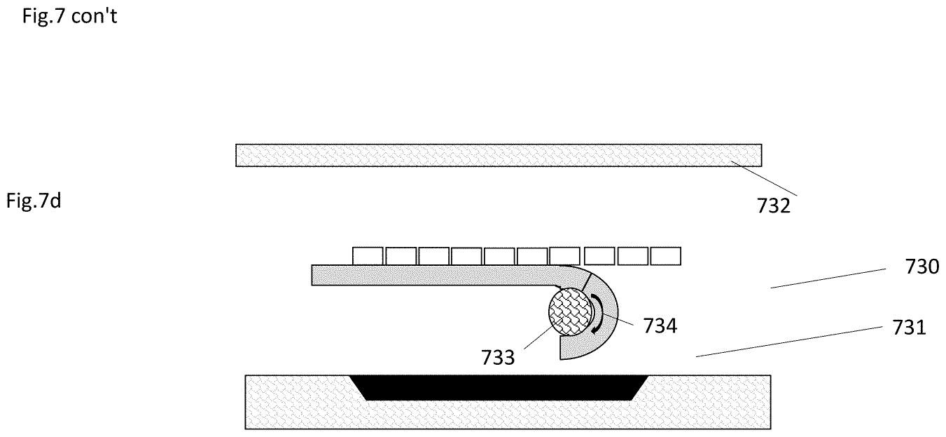

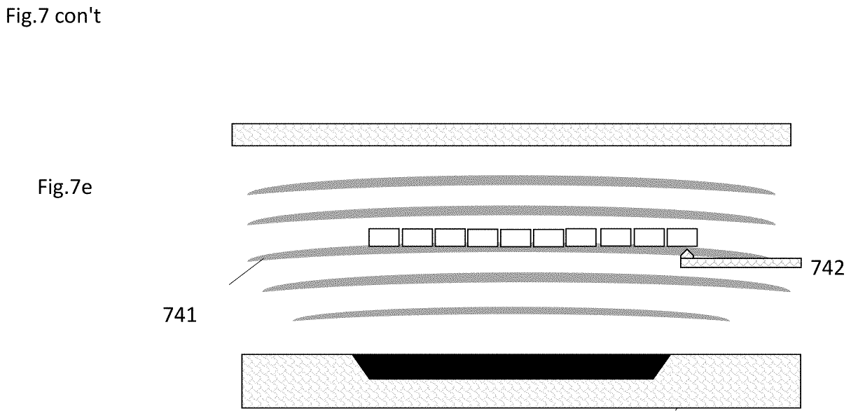

FIG. 7 shows an embodiment of chip detachment and floating mechanism from a diced wafer using acoustic wave levitation (also good for single chip case). As shown in FIG. 7a, the incoming wafer system 700 from wafer suppliers has a diced wafer 702 sitting on a piece of UV sensitive dicing tape 701 with all the necessary post dicing front surface treatment to ensure there is no front surface particles and contamination for chip-to-wafer or chip-to-chip bonding. Then the dicing tape is stretched to establish some gaps between the diced chips as shown in FIG. 7b. The process described in FIG. 7b is not necessary to get done on the proposed system. After the dicing tape stretching, as indicated in FIG. 7c, a UV radiation 721 is applied from the back side of the dicing tape to weaken the strength of the adhesive force. The whole diced wafer with dicing tape is then move into a acoustic wave levitation system 730 with acoustic wave generator 731 and acoustic wave reflector 732. Then the dicing tape is peeled off from the back of the tape by a cylindrical shape device 733 rotating along the direction indicated by the arrow 734 as shown in FIG. 7d. The acoustic wave levitation system is switched on and a standing wave 741 will be generated while the dicing tape is peeled off, which floats the isolated chips and allow pickup tool 742 to access individual chip from the chip back side for the subsequent steps such as chip flipping and chip bonding.

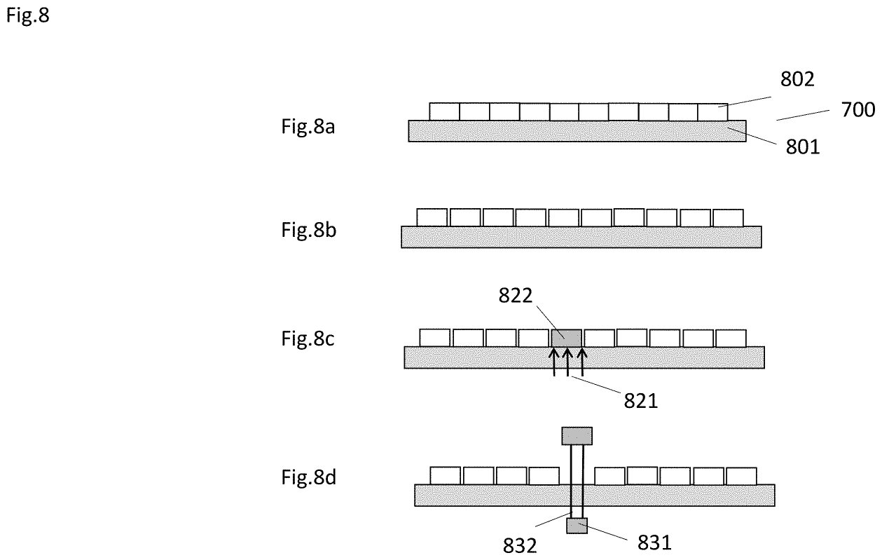

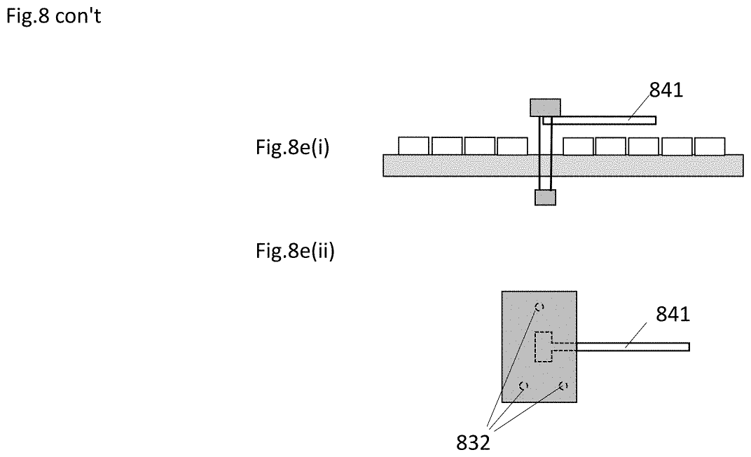

FIG. 8 shows an embodiment of chip detachment and pickup using pin-pushing with only the chip bottom surface touched. As shown in FIG. 8a, the incoming wafer system 800 from wafer suppliers has a diced wafer 802 sitting on a piece of UV sensitive dicing tape 801 with all the necessary post dicing front surface treatment to ensure there is no front surface particles and contamination for chip-to-wafer or chip-to-chip bonding. Then the dicing tape is stretched to establish some gaps between the diced chips as shown in FIG. 8b. The process described in FIG. 8b is not necessary to get done on the proposed system. After the dicing tape stretching, as shown in FIG. 8c, a local UV radiation 821 is shined behind the designated chip 822 to reduce the adhesive force so that the chip 822 can be pushed out mechanically with the pushing up tool 831 with pins 832 as shown in FIG. 8d. The chip is then picked up from the bottom side of the chip with pickup tool 841 as shown in FIG. 8e(i)—side view, and FIG. 8e(ii)-top down view.

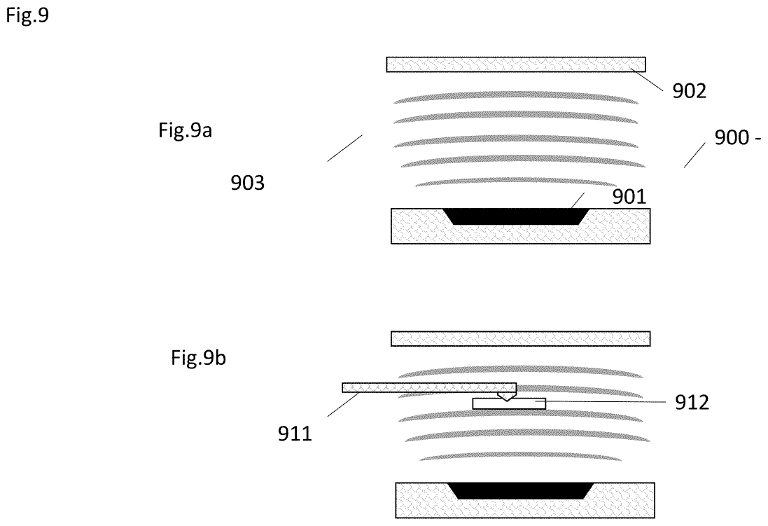

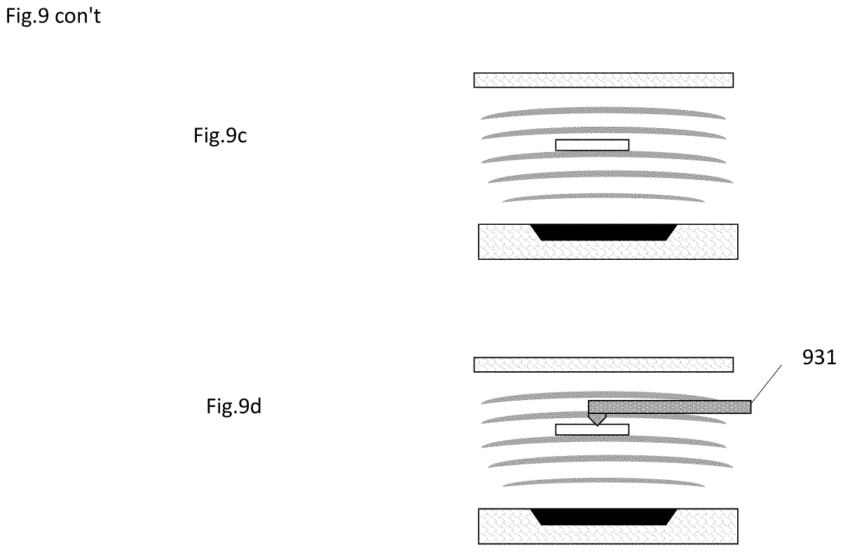

FIG. 9 shows an embodiment of flipped chip sitting stand by acoustic levitation in station 210 in FIG. 2. The 900 flipped chip sitting stand comprises an acoustic wave generator 901 and a wave reflector 902. A standing wave 903 between 901 and 902 is established which can be used to hold light objects in floating by balance its gravity against the acoustic wave holding force as shown in FIG. 9b. The chip 912 with it front side facing down can then be picked up from its bottom side by tool 911, which can be either a bonding head 221 from station 220 or pickup tool 231 from station 230 in FIG. 2.

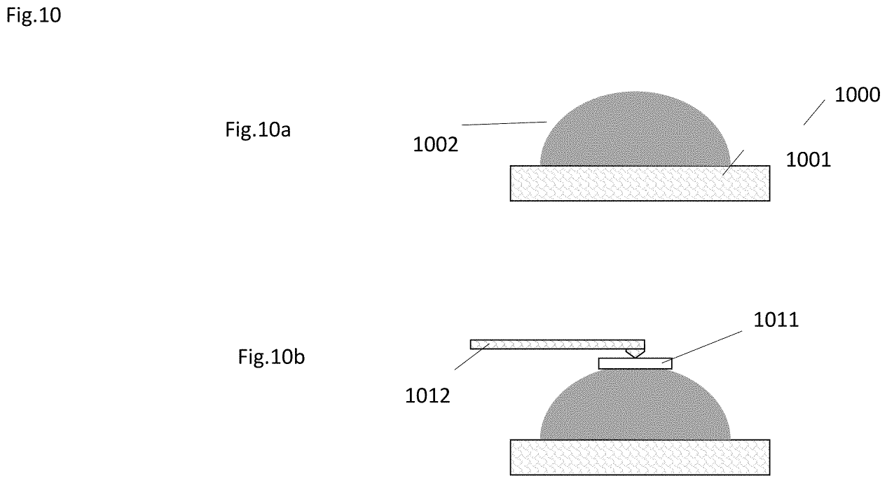

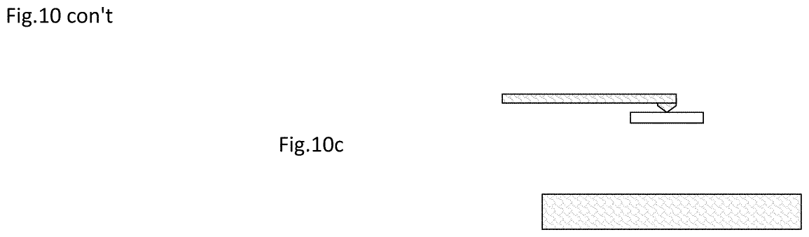

FIG. 10 shows an embodiment of flipped chip sitting stand using pure water surface tension. In details, the flipped chip sitting stand 1000 comprises a special treated hydrophobic surface 1001 to allow pure water drop 1002 set on as shown in FIG. 10a. The chip 1011, which sits on the top of the pure water drop 1002 supported by the surface tension, can then be picked up by pickup tool or bonding head 1012 from the chip back side without touching the chip front surface. After the pickup tool holds the chip securely, water on the chip can be dried by heating.

What is claimed is:

1. A chip bonder—a piece of equipment for chip-to-wafer and chip-to-chip bonding, comprises at least:
A chip supply/pickup station with a method to enable either a pickup/flip tool or a bonding head to access the backside surface of a chip, without touching the chip's front surface, either from a chip carrier or a diced wafer on a dicing tape;
A chip bonding station with a bonding head.

2. The system of claim 1, wherein said chip bonder further comprises a flipped chip sitting station, on which said chip is either picked, flipped then placed by said pickup/flip tool; or from which said chip is picked by said bonding head.

3. The system of claim 1, wherein said chip bonder further comprises a surface activation station using an ion plasma technology to activate the bonding surface of said chip.

4. The system of claim 1, wherein said chip carrier is an accessory of said chip bonder and is made by a piece of specially treated and shaped diamagnetic material being capable of carrying and floating said chip in a magnetic field to expose said chip's bottom surface for pickup.

5. The system of claim 1, wherein said chip from said diced wafer is charged from the chip backside through said dicing tape then is levitated to expose the chip bottom surface for pickup in an electrical field via electrostatic levitation.

6. The system of claim 1, wherein said chip from said diced wafer is picked up by a non-contact pickup tool via Bernoulli's Principle.

7. The system of claim 6, wherein said non-contact pickup tool at least comprises an air flow generator to create an air flow, and a sensor to provide the position information of the chip in respect to the surface of the non-contact pickup tool for a feedback control.

8. The system of claim 7, wherein said non-contact pickup tool further comprises an acoustic wave generator to avoid the chip front side touching by the pickup tool.

9. The system of the claim 6, wherein said non-contact pickup tool at least comprises a vacuum sucking inlet with a feedback control of airflow intakes, and a sensor to provide the position information of the chip in respect to the surface of the non-contact pickup tool for the feedback control.

10. The system of the claim 9, wherein said non-contact pickup tool further comprises an acoustic wave generator to avoid the chip front side touching by the pickup tool.

11. The system of the claim 1, wherein said chip from said diced wafer is picked up by either a pickup/flip tool or a bonding head after said dicing tape is peeled away from the chip back side with a tool after locally reducing the adhesive force of said dicing tape.

12. The system of the claim 1, wherein said chip from said diced wafer is levitated in an acoustic wave levitation station to allow either a pickup/flip tool or a bonding head to pick up from the chip back side after said dicing tape is peeled away from the chip back side with a tool.

13. The system of the claim 1, wherein said chip from said diced wafer is pushed from below through said dicing tape by a set of mechanical pins to exposure the chip back side to allow either a pickup/flip tool or a bonding head to pick it up.

14. The system of the claim 2, wherein said flipped chip sitting station at least comprise a flipped chip sitting stand, in which the chip is floating with it bottom surface up for pickup.

15. The system of the claim 14, wherein said flipped chip sitting stand is an acoustic wave levitation stand comprising at least an acoustic wave generator.

16. The system of the claim 14, wherein said flipped chip sitting stand comprises at least a specially treated hydrophobia surface to allow the formation of a pure water drop, whose surface tension is used to float the chip with its back side surface up for pickup.

17. The system of claim 16, where said flipped chip sitting stand further comprises a mechanism to fully remove the water from the picked chip surface.

18. The system of claim 4, wherein said piece of specially treated and shaped diamagnetic materials is a piece of pyrolytic carbon (PyC).
